(19) United States
(12) Patent Application Publication
(10) Pub. No.: US 2022/0393126 A1
(43) Pub. Date: Dec. 8, 2022

(54) MANUFACTURING METHOD FOR SEMICONDUCTOR FILM, PHOTODETECTOR ELEMENT, IMAGE SENSOR, AND SEMICONDUCTOR FILM

(71) Applicant: FUJIFILM Corporation, Tokyo (JP)

(72) Inventors: Masashi ONO, Shizuoka (JP); Masahiro TAKATA, Shizuoka (JP)

(73) Assignee: FUJIFILM Corporation, Tokyo (JP)

(21) Appl. No.: 17/881,556

(22) Filed: Aug. 4, 2022

Related U.S. Application Data
(63) Continuation of application No. PCT/JP2021/004477, filed on Feb. 8, 2021.

(30) Foreign Application Priority Data
Feb. 13, 2020 (JP) 2020-022576

(51) Int. Cl. H01L 51/44; H01L 27/30; H01L 51/00; H01L 51/42; C09K 11/02; C09K 11/66

(52) U.S. Cl. CPC H01L 51/447; H01L 27/307; H01L 51/0003; H01L 51/426; C09K 11/025; C09K 11/661; B82Y 20/00

(57) ABSTRACT

There is provided a semiconductor film that includes an aggregate of semiconductor quantum dots that contain a Pb atom, and a ligand that is coordinated to the semiconductor quantum dot, in which a ratio of the number of Pb atoms having a valence of 1 or less to the number of Pb atoms having a valence of 2 is 0.20 or less. There are also provided a photodetector element, an image sensor, and a manufacturing method for a semiconductor film.

### CROSS-REFERENCE TO RELATED APPLICATIONS

This application is a Continuation of PCT International Application No. PCT/JP2021/004477 filed on Feb. 8, 2021, which claims priority under 35 U.S.C § 119(a) to Japanese Patent Application No. 2020-022576 filed on Feb. 13, 2020. Each of the above application(s) is hereby expressly incorporated by reference, in its entirety, into the present application.

### BACKGROUND OF THE INVENTION

### 1. Field of the Invention

The present invention relates to a semiconductor film containing semiconductor quantum dots that contains a Pb atom, a photodetector element, an image sensor, and a method for manufacturing a semiconductor film.

### 2. Description of the Related Art

In recent years, attention has been focused on photodetector elements capable of detecting light in the infrared region in the fields such as smartphones, surveillance cameras, and in-vehicle cameras.

In the related art, a silicon photodiode in which a silicon wafer is used as a material of a photoelectric conversion layer has been used in a photodetector element that is used in an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth for achieving a high quantum efficiency, and thus it has not been widespread.

By the way, in recent years, research on semiconductor quantum dots has been advanced. A solar cell device, which has a semiconductor film containing PbS quantum dots treated with ZnI₂ and 3-mercaptopropionic acid as a photoelectric conversion layer, is disclosed in Santanu Pradhan, Alexandros Stavrinadis, Shuchi Gupta, Yu Bi, Francesco Di Stasio, and Gerasimos Konstantatos, “Trap-State Suppression and Improved Charge Transport in PbS Quantum Dot Solar Cells with Synergistic Mixed-Ligand Treatments”, Small 13, 1700598 (2017).

### SUMMARY OF THE INVENTION

In recent years, with the demand for performance improvement of an image sensor and the like, further improvement of various characteristics that are required in a photodetector element used in the image sensor and the like is also required. For example, it is required to further reduce the dark current of the photodetector element. In a case where the dark current of the photodetector element is reduced, a higher signal-to-noise ratio (SN ratio) can be obtained in the image sensor.

According to the study of the inventors of the present invention, it was found that the photodetector element having a photoelectric conversion layer formed of semiconductor quantum dots tended to have a relatively high dark current, and there was room for reducing the dark current. Here, the dark current is a current that flows in a case of not being irradiated with light.

Further, as a result of studies on the semiconductor film disclosed in Santanu Pradhan, Alexandros Stavrinadis, Shuchi Gupta, Yu Bi, Francesco Di Stasio, and Gerasimos Konstantatos, “Trap-State Suppression and Improved Charge Transport in PbS Quantum Dot Solar Cells with Synergistic Mixed-Ligand Treatments”, Small 13, 1700598 (2017), the inventors of the present invention found that the dark current tends to be high in this semiconductor film as well.

In consideration of the above circumstances, an object of the present invention is to provide a semiconductor film in which the dark current is reduced, a photodetector element, an image sensor, and a manufacturing method for a semiconductor film.

As a result of diligent studies on a semiconductor film containing an aggregate of semiconductor quantum dots that contain a Pb atom and containing a ligand that is coordinated to the semiconductor quantum dot, The inventors of the present invention found that the dark current can be reduced by reducing the ratio of the Pb atom having a valence of 1 or less, and have completed the present invention. The present invention provides the following aspects.

<1> A semiconductor film comprising:

an aggregate of semiconductor quantum dots that contain a Pb atom; and

a ligand that is coordinated to the semiconductor quantum dot,

in which a ratio of the number of Pb atoms having a valence of 1 or less to the number of Pb atoms having a valence of 2 is 0.20 or less.

<2> The semiconductor film according to <1>, in which the ratio of the number of Pb atoms having a valence of 1 or less to the number of Pb atoms having a valence of 2 is 0.10 or less.

<3> The semiconductor film according to <1>, in which the ratio of the number of Pb atoms having a valence of 1 or less to the number of Pb atoms having a valence of 2 is 0.05 or less.

<4> The semiconductor film according to any one of <1> to <3>, in which the semiconductor quantum dot contains PbS.

<5> The semiconductor film according to any one of <1> to <4>, in which the ligand contains at least one selected from a ligand containing a halogen atom or a polydentate ligand containing two or more coordination moieties.

<6> The semiconductor film according to <5>, in which the ligand containing a halogen atom is an inorganic halide.

<7> The semiconductor film according to <6> in which the inorganic halide contains a Zn atom.

<8> The semiconductor film according to any one of <5> to <7>, in which the ligand containing a halogen atom contains an iodine atom.

<9> A photodetector element comprising the semiconductor film according to any one of <1> to <8>.

<10> An image sensor comprising the photodetector element according to <9>.

<11> A manufacturing method for a semiconductor film, comprising:

a semiconductor quantum dot aggregate forming step of applying a semiconductor quantum dot dispersion liquid, which contains a semiconductor quantum dot containing a Pb atom, a first ligand coordinated to the semiconductor quantum dot, and a solvent, onto a substrate to form a film of an aggregate of semiconductor quantum dots;

a ligand exchange step of applying a ligand solution containing a second ligand different from the first ligand and containing a solvent onto the film of an aggregate of semiconductor quantum dots, the aggregate formed by the semiconductor quantum dot aggregate forming step, to exchange the first ligand coordinated to the semiconductor quantum dot with the second ligand contained in the ligand solution;

a rinsing step of bringing an aprotic solvent into contact with the film of an aggregate of semiconductor quantum dots after the ligand exchange step to rinse the film; and

a drying step of drying the semiconductor film after the rinsing step in an atmosphere of an oxygen-containing gas.

According to the present invention, it is possible to provide a semiconductor film in which the dark current is reduced, a photodetector element, an image sensor, and a manufacturing method for a semiconductor film.

### BRIEF DESCRIPTION OF THE DRAWINGS

FIG. 1 is a view illustrating an embodiment of a photodetector element.

### DESCRIPTION OF THE PREFERRED EMBODIMENTS

Hereinafter, the contents of the present invention will be described in detail.

In the present specification, “to” is used to mean that numerical values described before and after “to” are included as a lower limit value and an upper limit value, respectively.

In describing a group (an atomic group) in the present specification, in a case where a description of substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

<Semiconductor Film>

The semiconductor film according to the embodiment of the present invention is characterized by the following facts:

the semiconductor film includes an aggregate of semiconductor quantum dots that contain a Pb atom, and a ligand that is coordinated to the semiconductor quantum dot, in which a ratio of the number of Pb atoms having a valence of 1 or less to the number of Pb atoms having a valence of 2 is 0.20 or less.

In the semiconductor film the embodiment of the present invention, the ratio of the number of Pb atoms having a valence of 1 or less to the number of Pb atoms having a valence of 2 (the number of Pb atoms having a valence of 1 or less/the number Pb atoms having a valence of 2) is 0.20 or less, and thus it can be a semiconductor film in which the dark current is reduced. The details of the reason why such effects are obtained are unknown; however, it is presumed to be due to the following points.

Examples of the Pb atom having a valence of 2 include a Pb atom bonded (coordinated) to a ligand, a Pb atom bonded to a chalcogen atom, and a Pb atom bonded to a halogen atom. Examples of the Pb atom having a valence of 1 or less include a metallic Pb atom and a Pb atom in the dangling bond state.

Here, the amount of free electrons in the semiconductor film is conceived to be correlated with the dark current, and it is presumed that the dark current can be reduced by reducing the amount of free electrons.

It is conceived that in the semiconductor film containing an aggregate of semiconductor quantum dots that contain Pb atoms, the Pb atom having a valence of 1 or less plays a role of an electron donor, and it is presumed that the amount of free electrons in the semiconductor film can be reduced by reducing the ratio of the Pb atom having a valence of 1 or less.

For this reason, it is presumed that the dark current of the semiconductor film can be reduced by setting the ratio of the number of Pb atoms having a valence of 1 or less to the number of Pb atoms having a valence of 2 to 0.20 or less.

In the semiconductor film the embodiment of the present invention, the ratio of the number of Pb atoms having a valence of 1 or less to the number of Pb atoms having a valence of 2 is preferably 0.10 or less and more preferably 0.05 or less.

In the present specification, the value of the ratio of the number of Pb atoms having a valence of 1 or less to the number of Pb atoms having a valence of 2 in the semiconductor film is a value measured by X-ray photoelectron spectroscopy using an X-ray photoelectron spectroscopy (XPS) apparatus. Specifically, an XPS spectrum of the Pb4f (7/2) orbital of the semiconductor film is subjected to the curve fitting by the least squares method to carry out the waveform separation into a waveform W1 of which the intensity peak is present in a range of a bond energy of 137.8 to 138.2 eV and a waveform W2 of which the intensity peak is present in a range of a bond energy of 136.5 to 137 eV. Then, the ratio of a peak surface area S2 of the waveform W2 to the peak surface area S1 of the waveform W1 is calculated, and this value is taken as the ratio of the number of Pb atoms having a valence of 1 or less to the number of Pb atoms having a valence of 2 in the semiconductor film. In the present specification, the value of the above ratio is obtained by carrying out measurement at any three points in the film and taking the average value therefrom. In the present specification, it is preferable that the measurement by the X-ray photoelectron spectroscopy using the XPS apparatus is carried out under the conditions shown in Examples described later.

Here, in the measurement by X-ray photoelectron spectroscopy, the bond energy of the intensity peak may fluctuate slightly depending on the reference sample. In the semiconductor quantum dot in the present invention, a Pb—X bond between the Pb atom and an anion atom X paired with the Pb atom, where the Pb—X bond has a valence of 2, is present. Therefore, the contribution from Pb—X or a bond having an intensity peak at the same position of the bond energy as Pb—X is combinedly added to obtain the above-described peak surface area S1. Then, the contribution from a bond having an intensity peak at a position where the bond energy is lower than that is defined as the peak surface area S2. For example, as the ratio of the number of Pb atoms having a valence of 1 or less to the number of Pb atoms having a valence of 2 in a semiconductor film, it is possible to use a value that is calculated by using a waveform having an intensity peak at a bond energy of 138 eV as the waveform W1 and a waveform having an intensity peak at a bond energy of 136.8 eV as the waveform W2.

Examples of the means by which the ratio of the number of Pb atoms having a valence of 1 or less to the number of Pb atoms having a valence of 2 in the semiconductor film is set to be 0.20 or less include a method of bringing the semiconductor film into contact with an aprotic solvent to carry out rinsing at the time of manufacturing a semiconductor film or drying the semiconductor film in an atmosphere of an oxygen-containing gas; and a method of adjusting the number of times of the ligand exchange step to be reduced in the manufacturing process of the semiconductor film.

The thickness of the semiconductor film is not particularly limited; however, it is preferably 10 to 600 nm, more preferably 50 to 600 nm, still more preferably 100 to 600 nm, and even still more preferably 150 to 600 nm, from the viewpoint of obtaining high electrical conductivity. The upper limit of the thickness is preferably 550 nm or less, more preferably 500 nm or less, and still more preferably 450 nm or less.

The semiconductor film according to the embodiment of the present invention can be preferably used in the photoelectric conversion layer of the photodetector element. Hereinafter, the details of the semiconductor film according to the embodiment of the present invention will be described.

(Aggregate of Semiconductor Quantum Dots that Contain Pb Atom)

The semiconductor film the embodiment of the present invention has aggregate of semiconductor quantum dots that contain a Pb atom. The aggregate of semiconductor quantum dots means a form in which a large number of semiconductor quantum dots (for example, 100 or more quantum dots per 1 μm²) are arranged close to each other. In addition, the “semiconductor” in the present invention means a substance having a specific resistance value of 10-2Ωcm or more and 108 Ωcm or less.

Examples of the semiconductor quantum dot material that constitutes the semiconductor quantum dot include PbS, PbSe, PbTe, and PbSeS. Among them, due to the reason that the absorption coefficient of light in the infrared region is large, the lifetime of photocurrent is long, the carrier mobility is large, and the like, the semiconductor quantum dot preferably contains PbS or PbSe and more preferably contains PbS.

The semiconductor quantum dot may be a material having a core-shell structure in which a semiconductor quantum dot material is made to the nucleus (the core) and the semiconductor quantum dot material is covered with a coating compound. Examples of the coating compound include ZnS, ZnSe, ZnTe, ZnCdS, CdS, and GaP.

The band gap of the semiconductor quantum dot is preferably 0.5 to 2.0 eV. In a case where the semiconductor film according to the embodiment of the present invention is applied to the use application to a photodetector element application, more specifically to a photoelectric conversion layer of a photodetector element, it can be made into a photodetector element capable of detecting light of various wavelengths depending on the use application. For example, it is possible to obtain a photodetector element capable of detecting light in the infrared region. The upper limit of the band gap of the semiconductor quantum dot is preferably 1.9 eV or less, more preferably 1.8 eV or less, and still more preferably 1.5 eV or less. The lower limit of the band gap of the semiconductor quantum dot is preferably 0.6 eV or more and more preferably 0.7 eV or more.

The average particle diameter of the semiconductor quantum dots is preferably 2 to 15 nm. The average particle diameter of the semiconductor quantum dots is an average value of the particle diameters of ten semiconductor quantum dots which are randomly selected. A transmission electron microscope may be used for measuring the particle diameter of the semiconductor quantum dots.

Generally, a semiconductor quantum dot contains particles of various sizes from several nm to several tens of nm. In a case where the average particle diameter of semiconductor quantum dots is reduced to a size equal to or smaller than the Bohr radius of the electrons present in the inside of the semiconductor quantum dot, a phenomenon in which the band gap of the semiconductor quantum dot changes due to the quantum size effect occurs. In a case where the average particle diameter of semiconductor quantum dots is 15 nm or less, it is easy to control the band gap by the quantum size effect.

(Ligand)

The semiconductor film the embodiment of the present invention contains a ligand that is coordinated to the semiconductor quantum dot. Examples of the ligand include a ligand containing a halogen atom and a polydentate ligand containing two or more coordination moieties. The semiconductor film may contain only one kind of ligand or may contain two or more kinds thereof. Among the above, the semiconductor film preferably contains a ligand containing a halogen atom and a polydentate ligand. In a case where a ligand containing a halogen atom is used, the surface coverage of the semiconductor quantum dot by the ligand can be easily increased, and as a result, higher external quantum efficiency can be obtained. In a case where a polydentate ligand is used, the polydentate ligand is easily subjected to chelate coordination to the semiconductor quantum dot, and the peeling of the ligand from the semiconductor quantum dot can be suppressed more effectively, whereby excellent durability is obtained. Furthermore, in a case of being subjected to chelate coordination, steric hindrance between semiconductor quantum dots can be suppressed, and high electrical conductivity is easily obtained, whereby high external quantum efficiency is obtained. In addition, in a case where a ligand containing a halogen atom and a polydentate ligand are used in combination, a higher external quantum efficiency is easily obtained. As described above, the polydentate ligand is presumed to be subjected to chelate coordination to the semiconductor quantum dot. Furthermore, in a case where a ligand containing a halogen atom is further contained as the ligand that is coordinated to the semiconductor quantum dot, it is presumed that the ligand containing a halogen atom is coordinated in the gap where the polydentate ligand is not coordinated, and thus it is presumed that the surface defects of the semiconductor quantum dot can be further reduced. As a result, it is presumed that the external quantum efficiency can be further improved.

First, the ligand containing a halogen atom will be described. Examples of the halogen atom contained in the ligand include a fluorine atom, a chlorine atom, a bromine atom, and an iodine atom, and an iodine atom is preferable from the viewpoint of coordinating power.

The ligand containing a halogen atom may be an organic halide or may be an inorganic halide. Among the above, an inorganic halide is preferable due to the reason that it is easily coordinated to both the cation site and the anion site of the semiconductor quantum dot. In addition, the inorganic halide is preferably a compound containing a metal atom selected from a Zn atom, an In atom, and a Cd atom, and it is more preferably a compound containing a Zn atom. The inorganic halide is preferably a salt of a metal atom and a halogen atom due to the reason that the salt is easily ionized and easily coordinated to the semiconductor quantum dot.

Specific examples of the ligand containing a halogen atom include zinc iodide, zinc bromide, zinc chloride, indium iodide, indium bromide, indium chloride, cadmium iodide, cadmium bromide, and cadmium chloride, gallium iodide, gallium bromide, gallium chloride, tetrabutylammonium iodide, and tetramethylammonium iodide, and zinc iodide is particularly preferable.

It is noted that in the ligand containing a halogen atom, the halogen ion may be dissociated from the ligand described above, and the halogen ion may be coordinated on the surface of the semiconductor quantum dot. In addition, a portion of the ligand other than the halogen atom described above may also be coordinated on the surface of the semiconductor quantum dot. To give a description with a specific example, in the case of zinc iodide, zinc iodide may be coordinated on the surface of the semiconductor quantum dot, or the iodine ion or the zinc ion may be coordinated on the surface of the semiconductor quantum dot.

Next, the polydentate ligand will be described. Examples of the coordination moiety contained in the polydentate ligand include a thiol group, an amino group, a hydroxy group, a carboxy group, a sulfo group, a phospho group, and a phosphonate group. The polydentate ligand is preferably a compound containing a thiol group due to the reason that the compound is easily coordinated firmly on the surface of the Pb atom of the semiconductor quantum dot.

Examples of the polydentate ligand include a ligand represented by any one of Formulae (A) to (C).

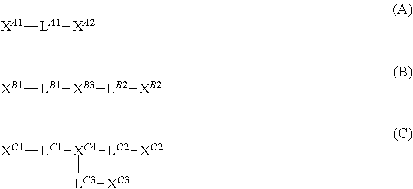

In Formula (A), X^{A1} and X^{A2} each independently represent a thiol group, an amino group, a hydroxy group, a carboxy group, a sulfo group, a phospho group, or a phosphonate group.

L^{A1} represents a hydrocarbon group.

In Formula (B), X^{B1} and X^{B2} each independently represent a thiol group, an amino group, a hydroxy group, a carboxy group, a sulfo group, a phospho group, or a phosphonate group.

X^{B3} represents S, O, or NH.

L^{B1} and L^{B2} each independently represent a hydrocarbon group.

In Formula (C), X^{c1} to X^{C3} each independently represent a thiol group, an amino group, a hydroxy group, a carboxy group, a sulfo group, a phospho group, or a phosphonate group.

X^{C4} represents N.

L^{C1} to L^{C3} each independently represent a hydrocarbon group.

The amino group represented by X^{A1}, X^{A2}, X^{B1}, X^{B2}, X^{C1}, X^{C2}, or X^{C3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and more preferably —NH₂.

The hydrocarbon group represented by L^{A1}, L^{B1}, L^{B2}, L^{C1}, L^{C2}, or L^{C3} is preferably an aliphatic hydrocarbon group. The aliphatic hydrocarbon group may be a saturated aliphatic hydrocarbon group or may be an unsaturated aliphatic hydrocarbon group. The hydrocarbon group preferably has 1 to 20 carbon atoms. The upper limit of the number of carbon atoms is preferably 10 or less, more preferably 6 or less, and still more preferably 3 or less. Specific examples of the hydrocarbon group include an alkylene group, an alkenylene group, and an alkynylene group.

Examples of the alkylene group include a linear alkylene group, a branched alkylene group, and a cyclic alkylene group. A linear alkylene group or a branched alkylene group is preferable, and a linear alkylene group is more preferable. Examples of the alkenylene group include a linear alkenylene group, a branched alkenylene group, and a cyclic alkenylene group. A linear alkenylene group or a branched alkenylene group is preferable, and a linear alkenylene group is more preferable. Examples of the alkynylene group include a linear alkynylene group and a branched alkynylene group, and a linear alkynylene group is preferable. The alkylene group, the alkenylene group, and the alkynylene group may further have a substituent. The substituent is preferably a group having 1 or more and 10 or less of atoms. Preferred specific examples of the group having 1 or more and 10 or less of atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a thiol group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (A), X^{A1} and X^{A2} are separated by L^{A1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

In Formula (B), X^{B1} and X^{B3} are separated by L^{B1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{B2} and X^{B3} are separated by L^{B2} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

In Formula (C), X^{C1} and X^{C4} are separated by L^{C1} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{C2} and X^{C4} are separated by L^{C2} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms. In addition, X^{C3} and X^{C4} are separated by L^{C3} preferably by 1 to 10 atoms, more preferably separated by 1 to 6 atoms, still more preferably separated by 1 to 4 atoms, even still more preferably separated by 1 to 3 atoms separated, and particularly preferably separated by 1 or 2 atoms.

It is noted that the description that X^{A1} and X^{A2} are separated by L^{A1} by 1 to 10 atoms means that the number of atoms constituting a molecular chain having the shortest distance, connecting X^{A1} and X^{A2}, is 1 to 10 atoms. For example, in a case of Formula (A1), X^{A1} and X^{A2} are separated by two atoms, and in cases of Formulae (A2) and (A3), X^{A1} and X^{A2} are separated by 3 atoms. The numbers added to the following structural formulae represent the arrangement order of atoms constituting a molecular chain having the shortest distance, connecting X^{A1} and X^{A2}.

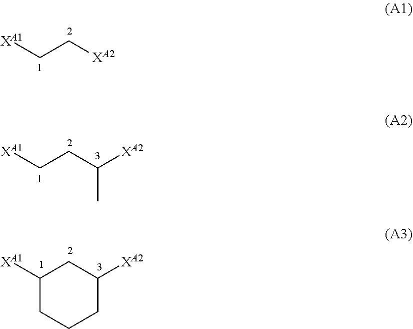

To give a description with a specific compound, 3-mercaptopropionic acid is a compound (a compound having the following structure) having a structure in which a portion corresponding to X^{A1} is a carboxy group, a portion corresponding to X^{A2} is a thiol group, and a portion corresponding to L^{A1} is an ethylene group. In 3-mercaptopropionic acid, X^{A1} (the carboxy group) and X^{A2} (the thiol group) are separated by L^{A1} (the ethylene group) by two atoms.

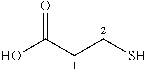

The same applies to the meanings that X^{B1} and X^{B3} are separated by L^{Bi} by 1 to 10 atoms, X^{B2} and X^{B3} are separated by L^{B2} by 1 to 10 atoms, X^{C1} and X^{C4} are separated by L^{C1} by 1 to 10 atoms, X^{C2} and X^{C4} are separated by L^{C2} by 1 to 10 atoms, and X^{C3} and X^{C4} are separated by L^{C3} by 1 to 10 atoms.

Specific examples of the polydentate ligand include 3-mercaptopropionic acid, thioglycolic acid, 2-aminoethanol, 2-aminoethanethiol, 2-mercaptoethanol, glycolic acid, ethylene glycol, ethylenediamine, aminosulfonic acid, glycine, aminomethyl phosphoric acid, guanidine, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propane-1-ol,1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-1-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, tartronic acid, and derivatives thereof. Due to the reason that a semiconductor film has a low dark current and a high external quantum efficiency, the polydentate ligand is preferably thioglycolic acid, 2-aminoethanol, 2-aminoethanethiol, 2-mercaptoethanol, glycolic acid, diethylenetriamine, tris(2-aminoethyl)amine, 1-thioglycerol, dimercaprol, ethylenediamine, ethylene glycol, aminosulfonic acid, glycine, (aminomethyl)phosphonic acid, guanidine, diethanolamine, 2-(2-aminoethyl)aminoethanol, homoserine, cysteine, thiomalic acid, malic acid, or tartaric acid, more preferably thioglycolic acid, 2-aminoethanol, 2-mercaptoethanol, or 2-aminoethanethiol, and still more preferably thioglycolic acid.

In addition, as the polydentate ligand, a compound in which the complex stability constant K1 between the polydentate ligand and the Pb atom of the semiconductor quantum dot is 6 or more is preferably used. The complex stability constant K1 of the polydentate ligand is more preferably 8 or more and still more preferably 10 or more. In a case where the complex stability constant K1 between the polydentate ligand and the Pb atom of the semiconductor quantum dot is 6 or more, the strength of the bond between the semiconductor quantum dot and the polydentate ligand can be increased.

The complex stability constant K1 is a constant determined by the relationship between a ligand and a metal atom which is a target of the coordinate bond, and it is represented by Expression (b).

Complex stability constant K1=[ML]/([M]×[L]) (b)

In Expression (b), [ML] represents the molar concentration of a complex formed by bonding a metal atom to a ligand, [M] represents the molar concentration of a metal atom contributing to the coordinate bond, and [L] represents the molar concentration of the ligand.

Practically, a plurality of ligands may be coordinated to one metal atom. However, in the present invention, the complex stability constant K1 represented by Expression (b) in a case where one ligand molecule is coordinated to one metal atom is defined as an indicator of the strength of the coordinate bond.

The complex stability constant K1 between the ligand and the metal atom can be determined by spectroscopy, magnetic resonance spectroscopy, potentiometry, solubility measurement, chromatography, calorimetry, solidifying point measurement, vapor pressure measurement, relaxation measurement, viscosity measurement, surface tension measurement, or the like. In the present invention, the complex stability constant K1 is determined using Sc-Database ver. 5.85 (Academic Software) (2010), which summarizes results from various methods and research institutes. In a case where the complex stability constant K1 is not present in the Sc-Database ver. 5.85, a value described in Critical Stability Constants, written by A. E. Martell and R. M. Smith, is used. In a case where the complex stability constant K1 is not described in the Critical Stability Constants, the above-described measurement method is used or a program PKAS method that calculates the complex stability constant K1 (The Determination and Use of Stability Constants, VCH (1988) written by A. E. Martell et. al.) is used to calculate the complex stability constant K1.

<Manufacturing Method for Semiconductor Film>

The manufacturing method for a semiconductor film according to the embodiment of the present invention includes;

a semiconductor quantum dot aggregate forming step of applying a semiconductor quantum dot dispersion liquid, which contains a semiconductor quantum dot containing a Pb atom, a first ligand coordinated to the semiconductor quantum dot, and a solvent, onto a substrate to form a film of an aggregate of semiconductor quantum dots;

a ligand exchange step of applying a ligand solution containing a second ligand different from the first ligand and containing a solvent onto the film of an aggregate of semiconductor quantum dots, the aggregate formed by the semiconductor quantum dot aggregate forming step, to exchange the first ligand coordinated to the semiconductor quantum dot with the second ligand contained in the ligand solution;

a rinsing step of bringing an aprotic solvent into contact with the film of an aggregate of semiconductor quantum dots after the ligand exchange step to rinse the film; and

a drying step of drying the semiconductor film after the rinsing step in an atmosphere of an oxygen-containing gas.

In the manufacturing method for a semiconductor film according to the embodiment of the present invention, the semiconductor quantum dot aggregate forming step and the ligand exchange step may be alternately repeated a plurality of times. That is, the operation of the semiconductor quantum dot aggregate forming step and the ligand exchange step as one cycle may be repeated a plurality of times, and then the rinsing step and the drying step may be sequentially carried out.

In addition, in the manufacturing method for a semiconductor film according to the embodiment of the present invention, the semiconductor quantum dot aggregate forming step, the ligand exchange step, and the rinsing step may be alternately repeated a plurality of times. That is, the operation of the semiconductor quantum dot aggregate forming step, the ligand exchange step, and the rinsing step as one cycle may be repeated a plurality of times, and then the drying step may be carried out.

Each step will be described in more detail below.

(Semiconductor Quantum Dot Aggregate Forming Step)

In the semiconductor quantum dot aggregate forming step, a semiconductor quantum dot dispersion liquid, which contains the semiconductor quantum dots that contain a Pb atom, the first ligand coordinated to the semiconductor quantum dot, and a solvent, is applied onto a substrate to form a film of aggregate of semiconductor quantum dots.

The semiconductor quantum dot dispersion liquid may be applied onto the surface of the substrate or may be applied onto another layer provided on the substrate. Examples of the other layer provided on the substrate include an adhesive layer for improving the intimate attachment between the substrate and the aggregate of semiconductor quantum dots, and a transparent conductive layer.

The semiconductor quantum dot dispersion liquid contains the semiconductor quantum dots having a Pb atom, the first ligand, and a solvent. The semiconductor quantum dot dispersion liquid may further contain other components as long as the effects of the present invention are not impaired.

The details of the semiconductor quantum dot containing a Pb atom, contained in the semiconductor quantum dot dispersion liquid, are as described above, and the preferred aspect thereof is also the same as described above. The content of the semiconductor quantum dot in the semiconductor quantum dot dispersion liquid is preferably 1 to 500 mg/mL, more preferably 10 to 200 mg/mL, and still more preferably 20 to 100 mg/mL. In a case where the content of the semiconductor quantum dot in the semiconductor quantum dot dispersion liquid is 1 mg/mL or more, the density of the semiconductor quantum dot on the substrate becomes high, and thus a good film is easily obtained. On the other hand, in a case where the content of the semiconductor quantum dot is 500 mg/mL or less, the film thickness of the film obtained by applying the semiconductor quantum dot dispersion liquid one time is hardly increased. As a result, in the following ligand exchange step, it is possible to sufficiently carry out the ligand exchange of the first ligand coordinated to the semiconductor quantum dot present in the film.

The first ligand contained in the semiconductor quantum dot dispersion liquid acts as a ligand that is coordinated to the semiconductor quantum dot and has a molecular structure that easily causes steric hindrance, and thus it is preferable that the dispersant also serves as a dispersing agent that disperses semiconductor quantum dots in the solvent.

From the viewpoint of improving the dispersibility of semiconductor quantum dots, the first ligand is preferably a ligand having at least 6 or more carbon atoms in the main chain and is more preferably a ligand having 10 or more carbon atoms in the main chain. The first ligand may be any one of a saturated compound or an unsaturated compound. Specific examples of the first ligand include decanoic acid, lauric acid, myristic acid, palmitic acid, stearic acid, behenic acid, oleic acid, erucic acid, oleyl amine, dodecyl amine, dodecanethiol, 1,2-hexadecanethiol, trioctylphosphine oxide, and cetrimonium bromide. The first ligand is preferably one that hardly remains in the film after the formation of the semiconductor film. Specifically, it is preferable that the molecular weight thereof is small. The first ligand is preferably oleic acid or oleyl amine from the viewpoint of imparting the dispersion stability to the semiconductor quantum dots and hardly remaining on the semiconductor film.

The content of the first ligand in the semiconductor quantum dot dispersion liquid is preferably 0.1 mmol/L to 500 mmol/L and more preferably 0.5 mmol/L to 100 mmol/L with respect to the total volume of the semiconductor quantum dot dispersion liquid.

The solvent contained in the semiconductor quantum dot dispersion liquid is not particularly limited; however, it is preferably a solvent that is difficult to dissolve the semiconductor quantum dots and easily dissolves the first ligand. The solvent is preferably an organic solvent. Specific examples thereof include an alkane [n-hexane, n-octane, or the like], benzene, and toluene. The solvent contained in the semiconductor quantum dot dispersion liquid may be only one kind or may be a mixed solvent in which two or more kinds are mixed.

The solvent contained in the semiconductor quantum dot dispersion liquid is preferably a solvent that does not easily remain in the formed semiconductor film. In a case where the solvent has a relatively low boiling point, the content of the residual organic substance can be suppressed when the semiconductor film has finally been obtained. In addition, the solvent is preferably a solvent having good wettability to the substrate. For example, in a case where the semiconductor quantum dot dispersion liquid is applied onto a glass substrate, the solvent is preferably an alkane such as hexane or octane.

The content of the solvent in the semiconductor quantum dot dispersion liquid is preferably 50% to 99% by mass, more preferably 70% to 99% by mass, and still more preferably 90% to 98% by mass, with respect to the total mass of the semiconductor quantum dot dispersion liquid.

The semiconductor quantum dot dispersion liquid is applied onto a substrate. The shape, structure, size, and the like of the substrate are not particularly limited, and the substrate can be appropriately selected depending on the intended purpose. The structure of the substrate may be a monolayer structure or a laminated structure. As the substrate, for example, a substrate composed of an inorganic material such as such, glass, or yttria-stabilized zirconia (YSZ), a resin, a resin composite material, or the like can be used. In addition, an electrode, an insulating film, or the like may be formed on the substrate. In that case, the semiconductor quantum dot dispersion liquid is applied onto the electrode or the insulating film on the substrate.

The method of applying a semiconductor quantum dot dispersion liquid onto a substrate is not particularly limited. Examples thereof include coating methods such as a spin coating method, a dipping method, an ink jet method, a dispenser method, a screen printing method, a relief printing method, an intaglio printing method, and a spray coating method.

The film thickness of the film of aggregate of the semiconductor quantum dots, formed by the semiconductor quantum dot aggregate forming step, is preferably 3 nm or more, more preferably 10 nm or more, and still more preferably 20 nm or more. The upper limit thereof is preferably 200 nm or less, more preferably 150 nm or less, and still more preferably 100 nm or less.

(Ligand Exchange Step)

In the ligand exchange step, a ligand solution containing a second ligand different from the first ligand and containing a solvent is applied onto the film of an aggregate of semiconductor quantum dots, the aggregate formed by the semiconductor quantum dot aggregate forming step, to exchange the first ligand coordinated to the semiconductor quantum dot with the second ligand contained in the ligand solution.

Examples of the second ligand include a ligand containing a halogen atom and a polydentate ligand containing two or more coordination moieties. Examples of the details thereof include those described in the section of the semiconductor film described above, and the same applies to the preferred range thereof.

The ligand solution that is used in the ligand exchange step may contain only one kind of the second ligand or may contain two or more kinds thereof. In addition, two or more kinds of ligand solutions may be used.

The solvent contained in the ligand solution is preferably selected appropriately according to the kind of the ligand contained in each ligand solution, and it is preferably a solvent that easily dissolves each ligand. In addition, the solvent contained in the ligand solution is preferably an organic solvent having a high dielectric constant. Specific examples thereof include ethanol, acetone, methanol, acetonitrile, dimethylformamide, dimethyl sulfoxide, butanol, and propanol. In addition, the solvent contained in the ligand solution is preferably a solvent that does not easily remain in the formed semiconductor film. From the viewpoints of easy drying and easy removal by washing, a low boiling point alcohol, a ketone, or a nitrile is preferable, and methanol, ethanol, acetone, or acetonitrile is more preferable. The solvent contained in the ligand solution is preferably one that does not mix with the solvent contained in the semiconductor quantum dot dispersion liquid. Regarding the preferred solvent combination, in a case where the solvent contained in the semiconductor quantum dot dispersion liquid is an alkane such as hexane or octane, it is preferable to use a polar solvent such as methanol or acetone as the solvent contained in the ligand solution.

The method for applying the ligand solution onto the aggregate of semiconductor quantum dots is the same as the method for applying the semiconductor quantum dot dispersion liquid onto the substrate, and the preferred aspect is also the same as described above.

(Rinsing Step)

In the rinsing step, an aprotic solvent is brought into contact with the film of an aggregate of semiconductor quantum dots after the ligand exchange step to rinse the film. In a case where the rinsing step is carried out, it is possible to remove the excess ligand contained in the film and the ligand eliminated from the semiconductor quantum dots. In addition, it is possible to remove the remaining solvent and other impurities. Then, by carrying out rinsing with an aprotic solvent, the ratio of the number of Pb atoms having a valence of 1 or less to the number of Pb atoms having a valence of 2 in the semiconductor film to be obtained can be set to be smaller. The aprotic solvent that is used in the rinsing step is preferably acetonitrile, acetone, methyl ethyl ketone, methyl isobutyl ketone, cyclopentanone, diethyl ether, tetrahydrofuran, cyclopentyl methyl ether, dioxane, ethyl acetate, butyl acetate, propylene glycol monomethyl ether acetate, hexane, octane, cyclohexane, benzene, toluene, chloroform, carbon tetrachloride, or dimethylformamide, more preferably acetonitrile or tetrahydrofuran, and still more preferably acetonitrile.

(Drying Step)

In the drying step, the semiconductor film after the rinsing step is dried in an atmosphere of an oxygen-containing gas. In a case where the drying is carried out in an atmosphere of an oxygen-containing gas, the ratio of the number of Pb atoms having a valence of 1 or less to the number of Pb atoms having a valence of 2 in the obtained semiconductor film can be set to be smaller.

The drying time is preferably 1 to 100 hours, more preferably 1 to 50 hours, and still more preferably 5 to 30 hours. The drying temperature is preferably 10° C. to 100° C., more preferably 20° C. to 90° C., and still more preferably 20° C. to 50° C. The oxygen concentration in the dry atmosphere is preferably 5% by volume or more, more preferably 10% by volume or more, and still more preferably 15% by volume or more.

<Photodetector Element>

The photodetector element according to the embodiment of the present invention includes the above-described semiconductor film according to the embodiment of the present invention. More preferably, the semiconductor film according to the embodiment of the present invention is included as the photoelectric conversion layer.

In the photodetector element, the thickness of the semiconductor film the embodiment of the present invention is preferably 10 to 600 nm, more preferably 50 to 600 nm, still more preferably 100 to 600 nm, and even still more preferably 150 to 600 nm. The upper limit of the thickness is preferably 550 nm or less, more preferably 500 nm or less, and still more preferably 450 nm or less.

Examples of the type of photodetector element include a photoconductor-type photodetector element and a photodiode-type photodetector element. Among the above, a photodiode-type photodetector element is preferable due to the reason that a high signal-to-noise ratio (SN ratio) is easily obtained.

In addition, since the semiconductor film according to the embodiment of the present invention has excellent sensitivity to the light having a wavelength in the infrared region, the photodetector element according to the embodiment of the present invention is preferably used as a photodetector element that detects light having a wavelength in the infrared region. That is, the photodetector element according to the embodiment of the present invention is preferably used as an infrared photodetector element.

The light having a wavelength in the infrared region is preferably light having a wavelength of more than 700 nm, more preferably light having a wavelength of 800 nm or more, and still more preferably light having a wavelength of 900 nm or more. In addition, the light having a wavelength in the infrared region is preferably light having a wavelength of 2,000 nm or less and more preferably light having a wavelength of 1,600 nm or less.

The photodetector element may be a photodetector element that simultaneously detects light having a wavelength in the infrared region and light having a wavelength in the visible region (preferably light having a wavelength in a range of 400 to 700 nm).

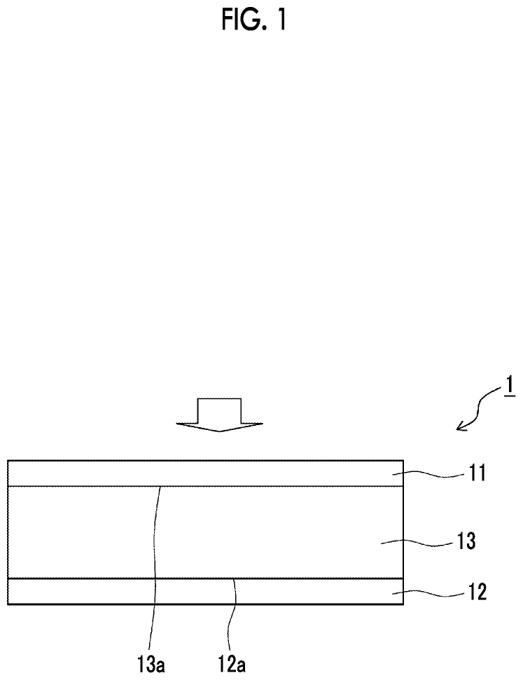

FIG. 1 illustrates an embodiment of a photodiode-type photodetector element. It is noted that an arrow in the figure represents the incidence ray on the photodetector element. A photodetector element 1 illustrated in FIG. 1 includes a lower electrode 12, an upper electrode 11 opposite to the lower electrode 12, and a photoelectric conversion layer 13 provided between the lower electrode 12 and the upper electrode 11. The photodetector element 1 illustrated in FIG. 1 is used by causing light to be incident from above the upper electrode 11.

The photoelectric conversion layer 13 is composed of the above-described semiconductor film according to the embodiment of the present invention.

The refractive index of the photoelectric conversion layer 13 with respect to the light of the target wavelength to be detected by the photodetector element is preferably 2.0 to 3.0, more preferably 2.1 to 2.8, and still more preferably 2.2 to 2.7. According to this aspect, in a case where the photodetector element is adopted as a constitutional element of the photodiode, it is easy to realize a high light absorbance, that is, a high external quantum efficiency.

The thickness of the photoelectric conversion layer 13 is preferably 10 to 600 nm, more preferably 50 to 600 nm, still more preferably 100 to 600 nm, and even still more preferably 150 to 600 nm. The upper limit of the thickness is preferably 550 nm or less, more preferably 500 nm or less, and still more preferably 450 nm or less.

The wavelength λ of the target light to be detected by the photodetector element and an optical path length L^{λ} of the light having the wavelength λ from a surface 12a of the lower electrode 12 on a side of the photoelectric conversion layer 13 to a surface 13a of the photoelectric conversion layer 13 on a side of the upper electrode 11 preferably satisfy the relationship of Expression (1-1), and more preferably satisfy the relationship of Expression (1-2). In a case where the wavelength λ and the optical path length L^{λ} satisfy such a relationship, in the photoelectric conversion layer 13, it is possible to arrange phases of the light (the incidence ray) incident from the side of the upper electrode 11 and phases of the light (the reflected light) reflected on the surface of the lower electrode 12, and as a result, the light is intensified by the optical interference effect, whereby it is possible to obtain a higher external quantum efficiency.

0.05+m/2≤L^{λ}/λ≤0.35+m/2 (1-1)

0.10+m/2≤L^{λ}/λ≤0.30+m/2 (1-2)

In the above expressions, λ is the wavelength of the target light to be detected by the photodetector element,

L^{λ} is the optical path length of light having a wavelength λ from a surface 12a of the lower electrode 12 on a side of the photoelectric conversion layer 13 to a surface 13a of the photoelectric conversion layer 13 on a side of the upper electrode 11, and

m is an integer of 0 or more.

m is preferably an integer of 0 to 4, more preferably an integer of 0 to 3, still more preferably an integer of 0 to 2, and particularly preferably 0 or 1.

Here, the optical path length means the product obtained by multiplying the physical thickness of a substance through which light transmits by the refractive index. To give a description with the photoelectric conversion layer 13 as an example, in a case where the thickness of the photoelectric conversion layer is denoted by d¹ and the refractive index of the photoelectric conversion layer with respect to the wavelength λ¹ is denoted by N¹, the optical path length of the light having a wavelength λ¹ and transmitting through the photoelectric conversion layer 13 is N¹×d¹. In a case where the photoelectric conversion layer 13 is composed of two or more laminated films or in a case where an interlayer described later is present between the photoelectric conversion layer 13 and the lower electrode 12, the integrated value of the optical path length of each layer is the optical path length L^{λ}.

The upper electrode 11 is preferably a transparent electrode formed of a conductive material that is substantially transparent with respect to the wavelength of the target light to be detected by the photodetector element. It is noted that in the present invention, the description of “substantially transparent” means that the light transmittance is 50% or more, preferably 60% or more, and particularly preferably 80% or more. Examples of the material of the upper electrode 11 include a conductive metal oxide. Specific examples thereof include tin oxide, zinc oxide, indium oxide, indium tungsten oxide, indium zinc oxide (IZO), indium tin oxide (ITO), and a fluorine-doped tin oxide (FTO).

The film thickness of the upper electrode 11 is not particularly limited, and it is preferably 0.01 to 100 more preferably 0.01 to 10 and particularly preferably 0.01 to 1 μm. It is noted that in the present invention, the film thickness of each layer can be measured by observing the cross section of the photodetector element 1 using a scanning electron microscope (SEM) or the like.

Examples of the material that forms the lower electrode 12 include a metal such as platinum, gold, nickel, copper, silver, indium, ruthenium, palladium, rhodium, iridium, osmium, or aluminum, the above-described conductive metal oxide, a carbon material, and a conductive polymer. The carbon material may be any material having conductivity, and examples thereof include fullerene, a carbon nanotube, graphite, and graphene.

The lower electrode 12 is preferably a thin film of a metal or conductive metal oxide (including a thin film formed by vapor deposition), or a glass substrate or plastic substrate having this thin film. The glass substrate or the plastic substrate is preferably glass having a thin film of gold or platinum, or glass on which platinum is vapor-deposited. The film thickness of the lower electrode 12 is not particularly limited, and it is preferably 0.01 to 100 μm, more preferably 0.01 to 10 μm, and particularly preferably 0.01 to 1 μm.

Although not illustrated in the drawing, a transparent substrate may be arranged on the surface of the upper electrode 11 on the light incident side (the surface opposite to the side of the photoelectric conversion layer 13). Examples of the kind of transparent substrate include a glass substrate, a resin substrate, and a ceramic substrate.

In addition, although not illustrated in the drawing, an interlayer may be provided between the photoelectric conversion layer 13 and the lower electrode 12 and/or between the photoelectric conversion layer 13 and the upper electrode 11. Examples of the interlayer include a blocking layer, an electron transport layer, and a hole transport layer. Examples of the preferred aspect thereof include an aspect in which the hole transport layer is provided at any one of a gap between the photoelectric conversion layer 13 and the lower electrode 12 or a gap between the photoelectric conversion layer 13 and the upper electrode 11. It is more preferable that the electron transport layer is provided at any one of a gap between the photoelectric conversion layer 13 and the lower electrode 12 or a gap between the photoelectric conversion layer 13 and the upper electrode 11, and the hole transport layer is provided at the other gap. The hole transport layer and the electron transport layer may be a single-layer film or a laminated film having two or more layers.

The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

The electron transport layer is a layer having a function of transporting electrons generated in the photoelectric conversion layer 13 to the upper electrode 11 or the lower electrode 12. The electron transport layer is also called a hole block layer. The electron transport layer is formed of an electron transport material capable of exhibiting this function. Examples of the electron transport material include a fullerene compound such as [6,6]-phenyl-C61-butyric acid methyl ester (PC₆₁BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport layer may be a single-layer film or a laminated film having two or more layers.

The hole transport layer is a layer having a function of transporting holes generated in the photoelectric conversion layer 13 to the upper electrode 11 or the lower electrode 12. The hole transport layer is also called an electron block layer. The hole transport layer is formed of a hole transport material capable of exhibiting this function. Examples of the hole transport material include poly(3,4-ethylenedioxythiophene):poly(4-styrenesulfonic acid) (PEDOT:PSS) and MoO₃. In addition, the organic hole transport material disclosed in paragraph Nos. 0209 to 0212 of JP2001-291534A can also be used. In addition, a semiconductor quantum dot can also be used as the hole transport material. Examples of the semiconductor quantum dot material that constitutes the semiconductor quantum dot include a nano particle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element]. Specific examples thereof include semiconductor materials having a relatively narrow band gap, such as PbS, PbSe, PbTe, PbSeS, InN, InAs, Ge, InGaAs, CuInS, CulnSe, CuInGaSe, InSb, HgTe, HgCdTe, Ag₂S, Ag₂Se, Ag₂Te, SnS, SnSe, SnTe, Si, and InP. A ligand may be coordinated on the surface of the semiconductor quantum dot.

<Image Sensor>

The image sensor according to the embodiment of the present invention includes the above-described photodetector element according to the embodiment of the present invention. Since the photodetector element according to the embodiment of the present invention also has excellent sensitivity to light having a wavelength in the infrared region, it can be particularly preferably used as an infrared image sensor.

The configuration of the image sensor is not particularly limited as long as it has the photodetector element according to the embodiment of the present invention and it is a configuration that functions as an image sensor.

The image sensor invention may include an infrared transmitting filter layer. The infrared transmitting filter layer preferably has a low light transmittance in the wavelength range of the visible region, more preferably has an average light transmittance of 10% or less, still more preferably 7.5% or less, and particularly preferably 5% or less in a wavelength range of 400 to 650 nm.

Examples of the infrared transmitting filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmitting filter layer forms a black color with a combination of two or more kinds of chromatic coloring materials or a coloring material containing a black coloring material. Examples of the combination of the chromatic coloring material in a case of forming a black color by a combination of two or more kinds of chromatic coloring materials include the following aspects (C1) to (C7).

(C1) an aspect containing a red coloring material and a blue coloring material.

(C2) an aspect containing a red coloring material, a blue coloring material, and a yellow coloring material.

(C3) an aspect containing a red coloring material, a blue coloring material, a yellow coloring material, and a purple coloring material.

(C4) an aspect containing a red coloring material, a blue coloring material, a yellow coloring material, a purple coloring material, and a green coloring material.

(C5) an aspect containing a red coloring material, a blue coloring material, a yellow coloring material, and a green coloring material.

(C6) an aspect containing a red coloring material, a blue coloring material, and a green coloring material.

(C7) an aspect containing a yellow coloring material and a purple coloring material.

The chromatic coloring material may be a pigment or a dye. It may contain a pigment and a dye. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. In a case where the infrared absorber is contained in the infrared transmitting filter layer, the wavelength of the light to be transmitted can be shifted to the longer wavelength side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use application of the image sensor. Examples of the filter layer include those that satisfy any one of the following spectral characteristics of (1) to (5).

(1): A filter layer in which the maximum value of the light transmittance in the film thickness direction in a wavelength range of 400 to 750 nm is 20% or less (preferably 15% or less and more preferably 10% or less), and the minimum value of the light transmittance in the film thickness direction in a wavelength range of 900 to 1,500 nm is 70% or more (preferably 75% or more and more preferably 80% or more).

(2): A filter layer in which the maximum value of the light transmittance in the film thickness direction in a wavelength range of 400 to 830 nm is 20% or less (preferably 15% or less and more preferably 10% or less), and the minimum value of the light transmittance in the film thickness direction in a wavelength range of 1,000 to 1,500 nm is 70% or more (preferably 75% or more and more preferably 80% or more).

(3): A filter layer in which the maximum value of the light transmittance in the film thickness direction in a wavelength range of 400 to 950 nm is 20% or less (preferably 15% or less and more preferably 10% or less), and the minimum value of the light transmittance in the film thickness direction in a wavelength range of 1,100 to 1,500 nm is 70% or more (preferably 75% or more and more preferably 80% or more).

(4): A filter layer in which the maximum value of the light transmittance in the film thickness direction in a wavelength range of 400 to 1,100 nm is 20% or less (preferably 15% or less and more preferably 10% or less), and the minimum value thereof in a wavelength range of 1,400 to 1,500 nm is 70% or more (preferably 75% or more and more preferably 80% or more).

(5): A filter layer in which the maximum value of the light transmittance in the film thickness direction in a wavelength range of 400 to 1,300 nm is 20% or less (preferably 15% or less and more preferably 10% or less), and the minimum value thereof in a wavelength range of 1,600 to 2,000 nm is 70% or more (preferably 75% or more and more preferably 80% or more).

Further, as the infrared transmitting filter, the films disclosed in JP2013-077009A, JP2014-130173A, JP2014-130338A, WO2015/166779A, WO2016/178346A, WO2016/190162A, WO2018/016232A, JP2016-177079A, JP2014-130332A, and WO2016/027798A can be used. As the infrared transmitting filter, two or more filters may be used in combination, or a dual bandpass filter that transmits through two or more specific wavelength ranges with one filter may be used.

The image sensor according to the embodiment of the present invention may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor according to the embodiment of the present invention may include a dielectric multi-layer film. Examples of the dielectric multi-layer film include those in which a plurality of layers are laminated by alternately laminating a dielectric thin film having a high refractive index (a high refractive index material layer) and a dielectric thin film having a low refractive index (a low refractive index material layer). The number of laminated layers of the dielectric thin film in the dielectric multi-layer film is not particularly limited; however, it is preferably 2 to 100 layers, more preferably 4 to 60 layers, and still more preferably 6 to 40 layers. The material that is used for forming the high refractive index material layer is preferably a material having a refractive index of 1.7 to 2.5. Specific examples thereof include Sb₂O₃, Sb₂S₃, Bi₂O₃, CeO₂, CeF₃, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. The material that is used for forming the low refractive index material layer is preferably a material having a refractive index of 1.2 to 1.6. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. The method for forming the dielectric multi-layer film is not particularly limited; however, examples thereof include ion plating, a vacuum deposition method using an ion beam or the like, a physical vapor deposition method (a PVD method) such as sputtering, and a chemical vapor deposition method (a CVD method). The thickness of each of the high refractive index material layer and the low refractive index material layer is preferably 0.1λ to 0.5λ in a case where the wavelength of the light to be blocked is λ (nm). Specific examples of the usable dielectric multi-layer film include the films disclosed in JP2014-130344A and JP2018-010296A.

In the dielectric multi-layer film, the transmission wavelength range is preferably present in the infrared region (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength range is preferably 70% or more, more preferably 80% or more, and still more preferably 90% or more. In addition, the maximum transmittance in the shielding wavelength range is preferably 20% or less, more preferably 10% or less, and still more preferably 5% or less. In addition, the average transmittance in the transmission wavelength range is preferably 60% or more, more preferably 70% or more, and still more preferably 80% or more. In addition, in a case where the wavelength at which the maximum transmittance is exhibited is denoted by a central wavelength λₜ₁, the wavelength range of the transmission wavelength range is preferably “the central wavelength λₜ₁±100 nm”, more preferably “the central wavelength λₜ₁±75 nm”, and still more preferably “the central wavelength λₜ₁±50 nm”.

The dielectric multi-layer film may have only one transmission wavelength range (preferably, a transmission wavelength range having a maximum transmittance of 90% or more) or may have a plurality of transmission wavelength ranges.

The image sensor according to the embodiment of the present invention may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. For example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include an organic material such as a siloxane resin or a fluororesin, and an inorganic particle such as a silica particle. In addition, the partition wall may be composed of a metal such as tungsten or aluminum.

In a case where the image sensor according to the embodiment of the present invention includes an infrared transmitting filter layer and a color separation layer, it is preferable that the color separation layer is provided on an optical path different from the infrared transmitting filter layer. In addition, it is also preferable that the infrared transmitting filter layer and the color separation layer are arranged two-dimensionally. The description that the infrared transmitting filter layer and the color separation layer are two-dimensionally arranged means that at least parts of both are present on the same plane.

The image sensor according to the embodiment of the present invention may include an interlayer such as a planarizing layer, an underlying layer, or an intimate attachment layer, an anti-reflection film, and a lens. As the anti-reflection film, for example, a film produced from the composition disclosed in WO2019/017280A can be used. As the lens, for example, the structure disclosed in WO2018/092600A can be used.

The image sensor according to the embodiment of the present invention can be preferably used as an infrared image sensor. In addition, the image sensor according to the embodiment of the present invention can be preferably used as a sensor that senses light having a wavelength of 900 to 2,000 nm and can be more preferably used as a sensor that senses light having a wavelength of 900 to 1,600 nm.

### EXAMPLES

Hereinafter, the present invention will be described more specifically with reference to Examples. Materials, amounts used, proportions, treatment details, treatment procedures, and the like shown in the following examples can be appropriately changed without departing from the gist of the present invention. Accordingly, a scope of the present invention is not limited to the following specific examples.

[Measuring Method for Ratio of Number of Pb Atoms Having Valence of 1 or Less to Number of Pb Atoms Having Valence of 2 in Semiconductor Film]

The ratio of the number of Pb atoms having a valence of 1 or less to the number of Pb atoms having a valence of 2 in the semiconductor film was measured by X-ray photoelectron spectroscopy using an X-ray photoelectron spectroscopy (XPS) apparatus.

The measurement conditions are as follows.
X-ray source: Monochromatic Al-K line (100 mmf, 25 W, 15 kV),
Measured region: 300 mm×300 mm (an area measurement)
Pass Energy: 55 eV,
Electrical charge correction: Yes (an electron gun and a low-speed ion gun are used in combination),
Photoelectron extraction angle: 45°

The evaluation was carried out focusing on the XPS spectrum (horizontal axis: bond energy, vertical axis: intensity) of the Pb4f (7/2) orbital. Specifically, an XPS spectrum of the Pb4f (7/2) orbital of the semiconductor film was subjected to the curve fitting by the least squares method to carry out the waveform separation into a waveform W1 of which the intensity peak was present at a bond energy of 138.0 eV and a waveform W2 of which the intensity peak was present at a bond energy of 136.8 eV. Then, the ratio of a peak surface area S2 of the waveform W2 to the peak surface area S1 of the waveform W1 is calculated, and this value is taken as the ratio of the number of Pb atoms having a valence of 1 or less to the number of Pb atoms having a valence of 2 in the semiconductor film.

[Preparation of Dispersion Liquid of PbS Quantum Dots]

1.3 mL of oleic acid, 2 mmol of lead oxide, and 19 mL of octadecene were weighed and taken in a flask and heated at 110° C. under vacuum for 90 minutes to obtain a precursor solution. Next, the temperature of the precursor solution was adjusted to 95° C., and the inside of the system was made into a nitrogen flow state. Next, 1 mmol of hexamethyldisilathiane was injected into the precursor solution together with 5 mL of octadecene. Immediately after the injection, the flask was naturally cooled, and at the stage where the temperature reached 30° C., 12 mL of hexane was added thereto, and a solution was recovered. An excess amount of ethanol was added to the solution, centrifugation was carried out at 10,000 rpm for 10 minutes, and the precipitate was dispersed in octane, to obtain a dispersion liquid (concentration: 40 mg/mL) of PbS quantum dots, in which oleic acid was coordinated as a ligand on the surface of the PbS quantum dot. The band gap of the PbS quantum dot in the obtained dispersion liquid of PbS quantum dot was estimated from light absorption measurement in the visible to infrared region by using an ultraviolet-visible-near infrared spectrophotometer (V-670, manufactured by JASCO Corporation), and it was approximately 1.33 eV.

### Examples 1 to 10 and Comparative Example 1

An indium tin oxide (ITO) film having a thickness of 100 nm and a titanium oxide film having a thickness of 20 nm were continuously formed on quartz glass by sputtering.

Next, the dispersion liquid of PbS quantum dots, prepared as described above, was added dropwise onto the titanium oxide film, and then spin coating was carried out at 2,500 rpm to obtain a semiconductor quantum dot aggregate film (a step 1).

Next, a ligand solution 1, which is a methanol solution of a ligand 1 (concentration: 0.01 v/v %) described in the table below, and a ligand solution, which is a methanol solution of a ligand 2 (concentration: 25 mmol/L) described in the table below, were added dropwise onto the semiconductor quantum dot aggregate film, and then the film was allowed to stand for 10 seconds and spin-dried at 2,500 rpm for 10 seconds. Next, the rinsing liquid described in the table below was added dropwise onto the semiconductor quantum dot aggregate film, and spin drying was carried out at 2,500 rpm for 20 seconds to carry out the ligand exchange of the ligand coordinated to the PbS quantum dot from oleic acid to the ligand 1 and the ligand 2 (a step 2).

The operation of the step 1 and step 2 as one cycle was repeated for 10 cycles, and a photoelectric conversion layer, which was the semiconductor film in which the ligand had been subjected to ligand exchange from oleic acid to the ligand 1 and the ligand 2, was formed to a thickness of 220 nm.

Next, the dispersion liquid of PbS quantum dots, prepared as described above, was added dropwise onto the above-described semiconductor film (the photoelectric conversion layer), and spin coating was carried out at 2,500 rpm to obtain a semiconductor quantum dot aggregate film (a step 1a).

Subsequently, an acetonitrile solution of ethanedithiol (concentration: 0.02 v/v %) was added dropwise onto this semiconductor quantum dot aggregate film, and then the film was allowed to stand for 30 seconds and spin-dried at 2,500 rpm for 10 seconds. Next, the rinsing liquid described in the table below was added dropwise onto the semiconductor quantum dot aggregate film, and spin drying was carried out at 2,500 rpm for 20 seconds to carry out the ligand exchange of the ligand coordinated to the PbS quantum dot from oleic acid to ethanedithiol (a step 2a).

The operation of the step 1a and step 2a as one cycle was repeated for two cycles, and an electron block layer which was the semiconductor film in which the ligand had been subjected to ligand exchange from oleic acid to ethanedithiol, was formed to a thickness of 40 nm.

Next, the formed laminated film (the laminated film of the photoelectric conversion layer and the electron block layer) was dried under the drying conditions shown in the table below.

Next, a gold electrode was produced on the semiconductor film (the electron block layer) by vapor deposition with a metal mask being interposed, whereby a photodiode-type photodetector element was manufactured. For the semiconductor film (the photoelectric conversion layer) of the manufactured photodetector element, the ratio of the number of Pb atoms having a valence of 1 or less to the number of Pb atoms having a valence of 2 (the Pb ratio) was measured. The measurement results of the Pb ratio are shown in the table below.

<Evaluation>

External quantum efficiency (EQE) and dark current were measured for each of the manufactured photodetector elements by using a semiconductor parameter analyzer (C4156, manufactured by Agilent Technologies, Inc.).

First, the current-voltage characteristics (I-V characteristics) were measured while sweeping the voltage from 0 V to −2 V without irradiating light, and the current value at −1 V was evaluated as the dark current.

Subsequently, the I-V characteristics were measured while sweeping the voltage from 0 V to −2 V in a state of carrying out irradiation with monochrome light of 940 nm. The external quantum efficiency (EQE) was calculated from the photocurrent value in a case where −1 V was applied.

TABLE 1

| | | | | Drying conditions | | | | | |
|---|---|---|---|---|---|---|---|---|---|
| | | | Rinsing | Dry | Drying | | Pb | EQE | Dark current |
| | Ligand 1 | Ligand 2 | liquid | atmosphere | time | | ratio | (%) | (A/cm²) |
| Example 1 | Thioglycolic acid | Zinc iodide | Acetonitrile | Nitrogen gas | 10 | hours | 0.13 | 55.3 | 5.3 × 10⁻⁸ |
| Example 2 | Thioglycolic acid | Zinc iodide | Acetonitrile | Nitrogen gas | 5 | hours | 0.14 | 55.1 | 6.2 × 10⁻⁸ |
| Example 3 | Thioglycolic acid | Zinc iodide | Acetonitrile | Nitrogen gas | 1 | hour | 0.19 | 54.9 | 7.2 × 10⁻⁸ |
| Example 4 | Thioglycolic acid | Zinc iodide | Acetonitrile | Dry air | 1 | hour | 0.09 | 54.2 | 3.7 × 10⁻⁸ |
| Example 5 | Thioglycolic acid | Zinc iodide | Acetonitrile | Dry air | 3 | hours | 0.06 | 54.8 | 3.1 × 10⁻⁸ |
| Example 6 | Thioglycolic acid | Zinc iodide | Acetonitrile | Dry air | 5 | hours | 0.04 | 55.2 | 2.9 × 10⁻⁸ |
| Example 7 | Thioglycolic acid | Zinc iodide | Acetonitrile | Dry air | 10 | hours | 0.03 | 55.8 | 2.6 × 10⁻⁸ |
| Example 8 | 3-mercaptopropionic | Zinc iodide | Acetonitrile | Dry air | 10 | hours | 0.10 | 55.4 | 8.1 × 10⁻⁸ |
| | acid | | | | | | | | |
| Example 9 | 2-mercaptoethanol | Zinc iodide | Acetonitrile | Dry air | 10 | hours | 0.08 | 52.1 | 4.1 × 10⁻⁸ |
| Example 10 | Thioglycolic acid | Tetrabutylammonium | Acetonitrile | Dry air | 10 | hours | 0.04 | 55.5 | 3.0 × 10⁻⁸ |
| | | iodide | | | | | | | |
| Comparative | 3-mercaptopropionic | Zinc iodide | Methanol | Nitrogen gas | 10 | hours | 0.39 | 51.8 | 5.7 × 10⁻⁷ |
| Example 1 | acid | | | | | | | | |

The value of the Pb ratio in the above table is a value of the ratio of the number of Pb atoms having a valence of 1 or less to the number of Pb atoms having a valence of 2, contained in the semiconductor film (the photoelectric conversion layer) of the manufactured photodetector element.

As shown in the above table, it was confirmed that the dark current densities of the photodetector elements of Examples are reduced by about one order of magnitude as compared with Comparative Example 1. The same effect can be obtained by replacing the rinsing liquid of Example 1 with tetrahydrofuran.

In a case where an image sensor is produced by a known method by using the photodetector element obtained in Example described and incorporating it into a solid-state imaging element together with an optical filter produced according to the methods disclosed in WO2016/186050A and WO2016/190162A, it is possible to obtain an image sensor having good visible and infrared imaging performance.

In each Example, the same effect can be obtained even in a case where the semiconductor quantum dots of the photoelectric conversion layer are changed to PbSe quantum dots.

### EXPLANATION OF REFERENCES

1: photodetector element
11: upper electrode
12: lower electrode
13: photoelectric conversion layer

What is claimed is:

1. A semiconductor film comprising:
an aggregate of semiconductor quantum dots that contain a Pb atom; and
a ligand that is coordinated to the semiconductor quantum dot,
wherein a ratio of the number of Pb atoms having a valence of 1 or less to the number of Pb atoms having a valence of 2 is 0.20 or less.

2. The semiconductor film according to claim 1,
wherein the ratio of the number of Pb atoms having a valence of 1 or less to the number of Pb atoms having a valence of 2 is 0.10 or less.

3. The semiconductor film according to claim 1,
wherein the ratio of the number of Pb atoms having a valence of 1 or less to the number of Pb atoms having a valence of 2 is 0.05 or less.

4. The semiconductor film according to claim 1,
wherein the semiconductor quantum dot contains PbS.

5. The semiconductor film according to claim 1,
wherein the ligand contains at least one selected from a ligand containing a halogen atom or a polydentate ligand containing two or more coordination moieties.

6. The semiconductor film according to claim 5,
wherein the ligand containing a halogen atom is an inorganic halide.

7. The semiconductor film according to claim 6,
wherein the inorganic halide contains a Zn atom.

8. The semiconductor film according to claim 5,
wherein the ligand containing a halogen atom contains an iodine atom.

9. A photodetector element comprising the semiconductor film according to claim 1.

10. An image sensor comprising the photodetector element according to claim 9.

11. A manufacturing method for a semiconductor film, comprising:
a semiconductor quantum dot aggregate forming step of applying a semiconductor quantum dot dispersion liquid, which contains a semiconductor quantum dot containing a Pb atom, a first ligand coordinated to the semiconductor quantum dot, and a solvent, onto a substrate to form a film of an aggregate of semiconductor quantum dots;
a ligand exchange step of applying a ligand solution containing a second ligand different from the first ligand and containing a solvent onto the film of an aggregate of semiconductor quantum dots, the aggregate formed by the semiconductor quantum dot aggregate forming step, to exchange the first ligand coordinated to the semiconductor quantum dot with the second ligand contained in the ligand solution;
a rinsing step of bringing an aprotic solvent into contact with the film of an aggregate of semiconductor quantum dots after the ligand exchange step to rinse the film; and
a drying step of drying the semiconductor film after the rinsing step in an atmosphere of an oxygen-containing gas.
